(19) United States
(12) Patent Application Publication
(10) Pub. No.: US 2008/0085471 A1
(43) Pub. Date: Apr. 10, 2008

(54) PHOTOLITHOGRAPHIC METHOD USING MULTIPLE PHOTOEXPOSURE APPARATUS

(76) Inventors: Brent A. Anderson, Jericho, VT (US); Jed H. Rankin, Burlington, VT (US)

Correspondence Address: SCULLY, SCOTT, MURPHY & PRESSER, P.C., 400 GARDEN CITY PLAZA, Suite 300, GARDEN CITY, NY, 11530, US

(21) Appl. No.: 11/539,994

(22) Filed: Oct. 10, 2006

(51) Int. Cl. G03F 7/20

(52) U.S. Cl. 430/312; 430/394

(57) ABSTRACT

A photoexposure method photoexposes a photosensitive material layer located over a substrate while using a first set of photoexposure conditions that includes use of a first photoexposure apparatus. The photoexposure method then photoexposes the once photoexposed photosensitive material layer located over the substrate while using a second set of photoexposure conditions that includes use of a second photoexposure apparatus different from the first photoexposure apparatus. One of the first set of photoexposure conditions and the second set of photoexposure conditions does not form a latent image within the photosensitive material layer.

### BACKGROUND

1. Field of the Invention

The invention relates generally to photolithographic methods. More particularly, the invention relates to photolithographic methods that provide enhanced efficiency.

2. Description of the Related Art

As semiconductor device technology has advanced, critical dimensional control of semiconductor features, such as gate electrodes, continues to be of prominent importance. In particular, gate electrode critical dimension typically has a considerable influence upon semiconductor circuit operating parameters.

Critical dimensions of semiconductor structures, such as gate electrodes, may also vary as a function of a particular location of the semiconductor features upon a semiconductor substrate. Such location dependent critical dimension variability may result from inhomogeneous photolithographic processes or apparatus, or alternatively inhomogeneous manufacturing processes or apparatus. Other sources of variability are not excluded.

Given that critical dimension control is significant within semiconductor structures, methods and apparatus for controlling critical dimension are clearly desirable. Particularly desirable are methods and apparatus that may be adapted to address location dependent variability in critically dimensioned semiconductor structures, such as gate electrodes.

Various photoexposure methods and apparatus having desirable characteristics have been disclosed in the semiconductor fabrication art.

For example, Fritzie et al., in U.S. Pat. No. 6,884,551, teaches a multiple photoexposure method for forming fine features on a substrate. The multiple photoexposure method uses: (1) a first photoexposure using a first mask for forming the fine features upon the substrate; and (2) a second photoexposure using a trim mask comprising gray tone features to further trim critical dimensions of the fine features. The gray-tone features may be sub-resolution, and a gray tone mask may have regions of differing transmissivities.

In addition, Fritzie et al., in U.S. Pat. No. 6,934,007 also teaches another multiple photoexposure method for forming fine features on a substrate. This other multiple photoexposure method uses a single mask which remains stationary, but with at least two photoexposures that use different settings. The multiple photoexposure method provides enhanced contrast of the fine features, absent photoalignment concerns when forming the fine features.

Further, Nolscher et al., in U.S. Pub. No. 2003/0143470, teaches yet another multiple photoexposure method for photoexposing a photoresist layer. This particular multiple photoexposure method uses: (1) a first photoexposure for photoexposing a principal structure and an auxiliary structure within the photoresist layer; and (2) a second photoexposure different from the first photoexposure for photoexposing the auxiliary structure only. The multiply photoexposed photoresist layer may then be developed to yield only the principal structure.

In addition, Scharnweber, in U.S. Pub. No. 2005/0213070, also teaches yet another multiple photoexposure method that uses multiple photoexposure apparatus including multiple photoexposure conditions. The multiple photoexposure method that uses the multiple photoexposure apparatus including the multiple photoexposure conditions provides for enhanced efficiency when fabricating microelectronic structures.

Still further, Pierrat, in U.S. Pat. No. 6,852,471, teaches a method for controlling photoexposure when using “full phase” shift masks. In a particular embodiment, the method provides for the same exposure conditions when using a phase shift mask and a trim mask, but with a difference between a relative dosing for the phase shift mask and the trim mask.

Finally, Wang et al., in U.S. Pat. No. 6,818,385 teaches a method for fabricating an integrated circuit that uses an opaque field phase shift mask. A particular embodiment uses the opaque field phase shift mask in conjunction with a single phase structure mask. The opaque field phase shift mask primarily defines regions requiring phase shifting and the single phase structure mask primarily defines regions not requiring phase shifting.

Semiconductor and microelectronic structure dimensions are certain to continue to decrease. Due to the continued decreases in dimensions, critical dimension control, in particular with respect to location dependent critical dimension variability, is likely to continue to be of considerable importance. Thus, desirable are photolithographic methods and apparatus that provide cost effective enhanced critical dimensional control, in particular as related to location dependent critical dimension variability.

### SUMMARY OF THE INVENTION

The invention provides a two-photoexposure apparatus method for forming a patterned photosensitive material layer over a substrate. The patterned photosensitive material layer is typically a patterned photoresist layer. The two-photoexposure apparatus method uses a first photoexposure apparatus and a second photoexposure apparatus different than the first photoexposure apparatus. Within the two-photoexposure apparatus method, one of: (1) a first set of photoexposure conditions that use the first photoexposure apparatus; and (2) a second set of photoexposure conditions that use the second photoexposure apparatus, does not provide a latent image when photoexposing a photosensitive material layer located over a substrate (i.e., one of the first set of photoexposure conditions and the second set of photoexposure conditions is sub-lithographic).

A first method in accordance with the invention includes photoexposing a photosensitive material layer located over a substrate while using a first set of photoexposure conditions that include use of a first photoexposure apparatus to form a once photoexposed photosensitive material layer located over the substrate. This particular method also includes photoexposing the once photoexposed photosensitive material layer located over the substrate while using a second set of photoexposure conditions that include use of a second photoexposure apparatus different from the first photoexposure apparatus to form a twice photoexposed photosensitive material layer located over the substrate. Within this particular method, one of the first set of photoexposure conditions and the second set of photoexposure conditions does not form a latent image within the photosensitive material layer.

Another photolithographic method in accordance with the invention includes photoexposing a photosensitive material layer located over a substrate while using a first set of primary photoexposure conditions that include use of a first photoexposure apparatus to form a once photoexposed photosensitive material layer located over the substrate. This other method also includes photoexposing the once photoexposed photosensitive material layer located over the substrate while using a second set of secondary photoexposure conditions that include use of a second photoexposure apparatus different from the first photoexposure apparatus to form a twice photoexposed photosensitive material layer located over the substrate. Within this other method, the second set of secondary photoexposure conditions alone does not form a latent image within the photosensitive material layer.

Yet another photolithographic method in accordance with the invention includes photoexposing a photosensitive material layer located over a substrate while using a first set of secondary photoexposure conditions that include use of a first photoexposure apparatus to form a once photoexposed photosensitive material layer located over the substrate and absent a latent image. This other method also includes photoexposing the once photoexposed photosensitive material layer located over the substrate while using a second set of primary photoexposure conditions that include use of a second photoexposure apparatus different from the first photoexposure apparatus to form a twice photoexposed photosensitive material layer located over the substrate and including a latent image.

### BRIEF DESCRIPTION OF THE DRAWINGS

The objects, features and advantages of the invention are understood within the context of the Description of the Preferred Embodiments, as set forth below. The Description of the Preferred Embodiments is understood within the context of the accompanying drawings, which form a material part of this disclosure, wherein:

FIG. 1 shows a schematic block diagram illustrating a sequential photoexposing of a photosensitive material layer located upon a substrate in accordance with the invention.

FIG. 2 and FIG. 3 show photomask patterns and resulting latent patterns within a photoexposed photosensitive material layer that may result from using the photomasks in accordance with the embodiment of the invention that is illustrated in FIG. 1.

### DESCRIPTION OF THE PREFERRED EMBODIMENT

The invention, which comprises a two-photoexposure apparatus method for photoexposing a photosensitive material layer, and more particularly a photosensitive photoresist material layer, is understood within the context of the description below. The description below is understood within the context of the drawings described above. Since the drawings are intended for illustrative purposes, the drawings are not necessarily drawn to scale.

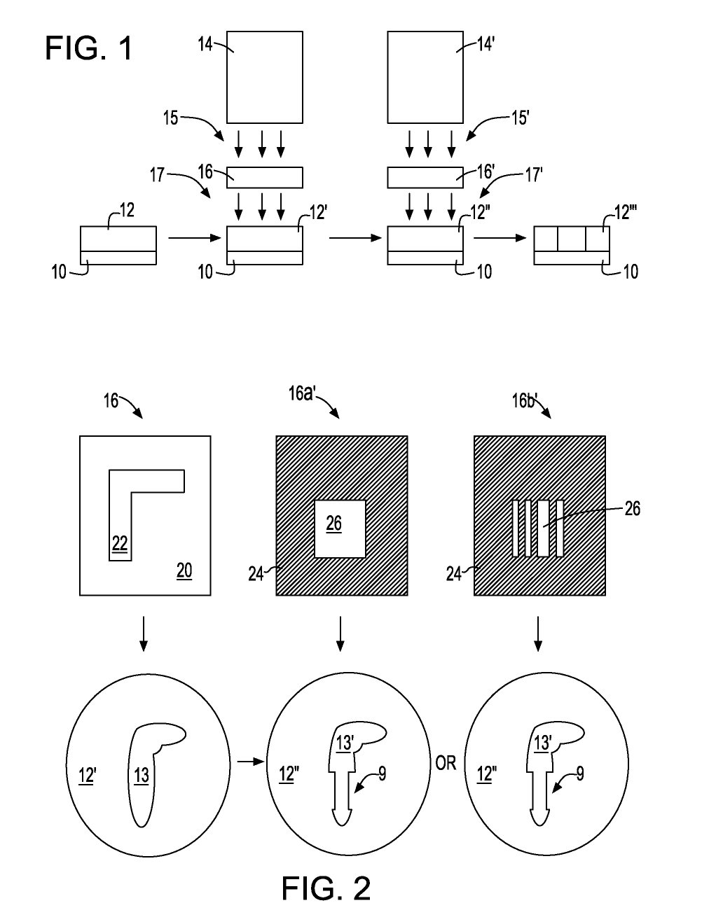

FIG. 1 shows a schematic block diagram illustrating in-part an apparatus for photoexposure processing of a photosensitive material layer (i.e., typically photoexposing a photoresist material layer) located upon a substrate in accordance with an embodiment of the invention.

FIG. 1 first shows a substrate 10. A photosensitive material layer 12 is located upon the substrate 10.

The substrate 10 may comprise any of several materials from which microelectronic substrates may conventionally be fabricated. The materials may include, but are not limited to dielectric materials, semiconductor materials and conductor materials. The substrate 10 may also comprise a laminate including any one or all of the foregoing dielectric materials, semiconductor materials and conductor materials. Typically, the substrate 10 comprises at least in part a semiconductor material, often in the form of a semiconductor substrate.

Such a semiconductor material may comprise, but is not limited to: a bulk semiconductor substrate, a semiconductor-on-insulator (SOI) substrate or a hybrid orientation (HOT) substrate. Other semiconductor substrates are not excluded and may be contemplated. Semiconductor-on-insulator substrates comprise a base semiconductor substrate. A buried dielectric layer is located upon the base semiconductor substrate and a surface semiconductor layer is located upon the buried dielectric layer. Semiconductor-on-insulator (SOI) substrates may be fabricated using layer transfer methods, laminating methods and separation by implantation of oxygen (SIMOX) methods.

Hybrid orientation (HOT) substrates comprise multiple regions of differing crystallographic orientation. Hybrid orientation (HOT) substrates may also be fabricated using layer transfer methods and laminating methods.

The substrate 10 may also comprise microelectronic devices, and in particular semiconductor devices. Non-limiting examples of such microelectronic devices include resistors, transistors, diodes and capacitors.

Within the embodiment that is illustrated in FIG. 1, the substrate 10 typically comprises a semiconductor substrate of any of the varieties described above. The semiconductor substrate typically also comprises semiconductor devices.

The photosensitive material layer 12 typically comprises a photoresist material, although the embodiment is not typically intended to be so limited. In general, the photosensitive material layer 12 may comprise any one or more of photosensitive inorganic materials, photosensitive organic materials and photosensitive composite materials which incident to photoexposure will benefit from the method of the invention.

When comprised of a photosensitive photoresist material, as is typically most common within the context of the instant embodiment, the photosensitive material layer 12 may also comprise any of several photoresist materials. Non-limiting examples of photoresist materials include positive photoresist materials, negative photoresist materials and hybrid photoresist materials. Typically, such a photoresist material is located and formed upon the substrate 10 to form the photosensitive material layer 12 while using an otherwise generally conventional spin coating method followed by a thermal curing method. When comprising a photoresist material, the photosensitive material layer 12 has a thickness from about 500 to about 10000 angstroms.

FIG. 1 also shows, in a schematic block diagram illustration format, photoexposure components used within a two-photoexposure apparatus method in accordance with the instant embodiment.

FIG. 1 first shows a first photoexposure apparatus 14 from which issues a first photoexposure radiation beam 15. The first photoexposure radiation beam 15 passes through a first mask 16 to provide a first photoexposure radiation beam 17. The first photoexposure radiation beam 17 photoexposes the photosensitive material layer 12 located upon substrate 10 to provide a once photoexposed photosensitive material layer 12′ located upon the substrate 10.

The first photoexposure apparatus 14 will typically have a photoexposure radiation wavelength selected from the group consisting of 193 nm, 248 nm and 365 nm photoexposure radiation wavelengths. Also intended to be included for the first photoexposure apparatus 14 are electron beam photoexposure apparatus, x-ray beam photoexposure apparatus and other suitable non-optical photoexposure apparatus.

The first photoexposure apparatus 14 is used within a first photoexposure method that also includes the use of other first photoexposure conditions (i.e., in addition to the first photoexposure apparatus 14 and the first mask 16) when photoexposing the photosensitive material layer 12 to provide the once-photoexposed photosensitive material layer 12′ while using the first photoexposure radiation beam 17. These other first photoexposure conditions may include, but are not limited to: (1) a first photoexposure radiation beam 17 degree of coherency; (2) a first photoexposure radiation beam 17 annularity; (3) a first photoexposure radiation beam 17 polarity; (4) a time profile with respect to the first photoexposure radiation beam 17; and (5) an orientation of the first photoexposure radiation beam 15 or 17 with respect to the first mask 16.

Within the context of the instant embodiment, a photoexposure radiation beam degree of coherency is understood as a ratio of an output-side numerical aperture of a photoexposure apparatus to an input-side numerical aperture of a downstream projection objective used within the photoexposure apparatus. Small values of a degree of coherence correspond to substantially complete coherent radiation.

An annularity of a photoexposure radiation beam is understood as a radial intensity distribution of the photoexposure radiation beam in a pupil plane. The photoexposure radiation beam may be along an optical axis or off-axis with respect to the optical axis.

A polarity of a photoexposure radiation beam is understood as the radial symmetry of an off-axis photoexposure radiation beam. For example, such a radial symmetry may be manifested as a dipole symmetry or a quadrupole symmetry.

A time profile of a photoexposure is understood to include not only the photoexposure time period itself, but also a time variation in a photoexposure radiation beam intensity during the photoexposure time period.

Finally, an orientation of a photoexposure radiation beam with respect to a mask is intended as a geometric orientation with respect to the mask.

The first mask 16 may comprise any of several mask types that are otherwise generally conventional in the semiconductor fabrication art. Non-limiting examples of such mask types include alternating phase shift masks, attenuated phase shift masks and binary masks. Other types of mask constructions are clearly not excluded. In addition, for certain types of first photoexposure radiation beams 15/17 a mask may be neither required nor desirable. These types of photoexposure radiation beams for which masks are neither required nor desirable include, but are not limited to electron beams, x-ray beams and other non-optical photoexposure radiation beams that are disclosed above.

The first mask 16 may use materials of construction that are otherwise generally conventional in the photolithographic art. Typically, the first mask 16 will comprise a transparent substrate having at least one patterned feature located thereupon. Specific mask types and materials of construction are disclosed in greater detail below. Generally, the first mask 16 comprises a pattern that will typically include at least two types of regions selected from group consisting of transparent regions, opaque regions and attenuated regions.

FIG. 1 also shows a second photoexposure apparatus 14′ from which issues a second photoexposure radiation beam 15′. The second photoexposure radiation beam 15′ passes through a second mask 16′ to yield a second photoexposure radiation beam 17′. The second photoexposure radiation beam 17′ is used to photoexpose the once photoexposed photosensitive material layer 12′ located upon the substrate 10 to form a twice photoexposed photosensitive material layer 12″ located upon substrate 10.

Within the instant embodiment, the second photoexposure apparatus 14′ may be selected from the same group of photoexposure apparatus as the first photoexposure apparatus 14. Such a group of photoexposure apparatus includes, but is not limited to: 193 nm, 248 nm and 365 nm photoexposure apparatus, as well as e-beam photoexposure apparatus, x-ray photoexposure apparatus and other non-optical photoexposure apparatus. At least some of the first photoexposure apparatus 14 and the second photoexposure apparatus 14′ that are disclosed above are projection photoexposure apparatus.

Similarly with the first photoexposure apparatus 14, the second photoexposure apparatus 14′ will also be used within the context of a second set of photoexposure conditions that include parameters selected from the group including but not limited to: (1) a second photoexposure radiation beam 17′ degree of coherency; (2) a second photoexposure radiation beam 17′ annularity; (3) a second photoexposure radiation beam 17′ polarity; (4) a time profile with respect to the second photoexposure radiation beam 17′; and (5) an orientation of the second photoexposure radiation beam 15′ or 17′ with respect to the second mask 16′.

The second photoexposure radiation beam 15′ or 17′ is thus similar with the first photoexposure radiation beam 15 or 17. In particular, the second photoexposure radiation beam 15′ or 17′ and the first photoexposure radiation beam 15 or 17 may have the same photoexposure radiation wavelength or a different photoexposure radiation wavelength. Other optical conditions for the second photoexposure radiation beam 15′ or 17′ and the first photoexposure radiation beam 15 or 17 may also be the same or different.

The second mask 16′ may be selected from the same group of masks as the first mask 16. Non-limiting examples of the group of second masks 16′ include alternating phase shift photomasks, attenuated phase shift photomasks and binary photomasks. Other types of photomasks are not excluded. In accordance with disclosure above, under circumstances where the second photoexposure apparatus 14′ uses a direct writing method, such as an electron beam method or an alternative direct writing method, a photomask may not be needed.

FIG. 1 finally shows a patterned photosensitive material layer 12′″ that is located upon the substrate 10. The patterned photosensitive material layer 12′″ results from development of the twice photoexposed photosensitive material layer 12″

Although not independently illustrated within the schematic diagram of FIG. 1, the embodiment also contemplates that either one or both of the once photoexposed photosensitive material layer 12′ and the twice photoexposed photosensitive material layer 12″ may be subjected to an optional thermal annealing process cycle prior to any additional processing of the once photoexposed photosensitive material layer 12′ or the twice photoexposed photosensitive material layer 12″. Such additional thermal processing may be provided at a temperature from about 60 to about 200 degrees centigrade for a time period from about 10 seconds to about 10 minutes. Such an additional thermal annealing processing exposure may in certain circumstances be intended to appropriately modify a residual chemical reaction rate of an appropriate photosensitive material to provide a stabilized once photoexposed photosensitive material layer 12′ or a stabilized twice photoexposed photosensitive material layer 12″.

Within the instant embodiment, the first photoexposure apparatus 14 is used within a first photoexposure method that also uses a first set of photoexposure conditions in accordance the photoexposure parameters disclosed above. In addition, the second photoexposure apparatus 14″ is used within a second photoexposure method that uses a second set of photoexposure conditions in accordance with the photoexposure parameters disclosed above. Within the embodiment, the first photoexposure apparatus 14 is different than the second photoexposure apparatus 14′ and generally also physically separate from the second photoexposure apparatus 14′. Within the embodiment, one of the first set of photoexposure conditions that includes use of the first apparatus 14 and the second set of photoexposure conditions that includes use of the second apparatus 14′ does not form a latent image within a photosensitive material layer (i.e., typically a photoresist layer) that is photoexposed using the first photoexposure method and the second photoexposure method. Thus, within the instant embodiment, a primary patterning of a blanket photoresist layer results primarily from only one of two photoexposures within a two photoexposure method. A second exposure within the two photoexposure method slightly modifies a photoresist material surface chemistry, which in turn results in a slight modification of a dimension of a latent image.

Within the embodiment, typically, one of the first photoexposure apparatus 14 and the second photoexposure apparatus 14′ is a comparatively expensive photoexposure apparatus that is used for photoexposing a primary fine pattern (i.e., a latent image) within the once photoexposed photosensitive material layer 12′. The other of the first photoexposure apparatus 14 and the second photoexposure apparatus 14′ is a comparatively inexpensive photoexposure apparatus that is used for providing a sub-threshold dose to the photosensitive material layer 12 or the once photoexposed photosensitive material layer 12′ so that specific locations within the latent image may be further controlled sub-lithographically (i.e., location dependent critical dimension control).

The embodiment contemplates that the comparatively more expensive of the first photoexposure apparatus 14 and the second photoexposure apparatus 14′ (and the corresponding first set of exposure conditions and second set of exposure conditions) may be used either first or second when photoexposing the photosensitive material layer 12 or the once photoexposed photosensitive layer 12′ upon the substrate 10 that is illustrated within the schematic diagram of FIG. 1 to provide the once photoexposed photosensitive material layer 12′ upon the substrate 10 and ultimately the twice photoexposed photosensitive material layer 12″ upon the substrate 10.

The embodiment also contemplates that the first mask 16 and the second mask 16′ will generally correlate with the first photoexposure apparatus 14 and the second photoexposure apparatus 14′ with respect to complexity, sophistication and cost (i.e., a generally more expensive photoexposure apparatus of the photoexposure apparatus 14 and the second photoexposure apparatus 14′ will typically include a generally more expensive photomask).

The instant embodiment also contemplates that the two-photoexposure apparatus method in accordance with the invention is typically undertaken using a more expensive and more precise of the first photoexposure apparatus 14 and the second photoexposure apparatus 14′ followed by the less expensive and less precise of the first photoexposure apparatus 14 and the second photoexposure apparatus 14′. However, as will be illustrated within the context of the examples that follow, the less expensive and less precise of the first photoexposure apparatus 14 and the second photoexposure apparatus 14′ may also be used prior to the more expensive and more precise of the first photoexposure apparatus 14 and the second photoexposure apparatus 14′.

In addition, although the instant embodiment that is illustrated in FIG. 1 illustrates the invention within the context of only two photoexposures of a photosensitive material layer 12 to ultimately provide a patterned photosensitive material layer 12′″ that typically comprises a patterned photoresist layer, the invention is also not limited to only two photoexposures of a photosensitive material layer. Rather the invention contemplates the use of at least two photoexposures of a photosensitive material layer when forming a patterned photosensitive material layer from the photosensitive material layer.

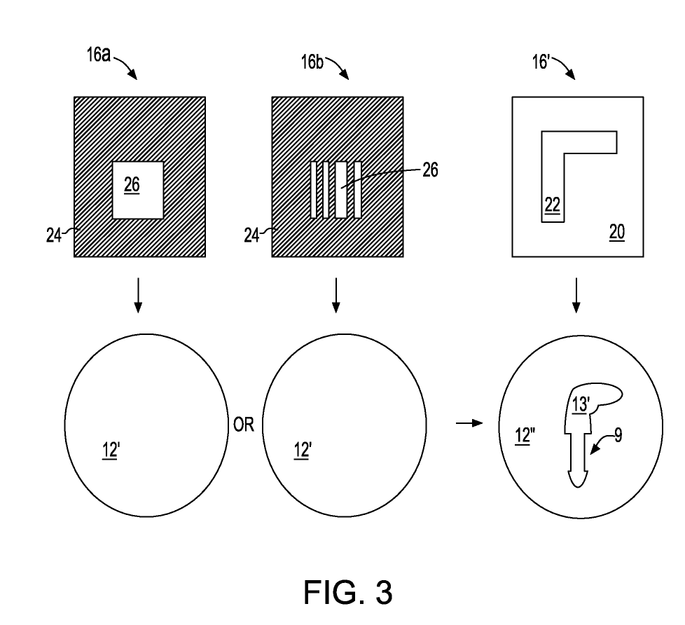

FIG. 2 shows a series of schematic plan-view diagrams of photomasks and photomask patterns that may be used within the context of the instant embodiment to form the patterned photosensitive material layer 12′″ (i.e., typically a patterned photoresist layer) located over the substrate 10 that is illustrated in FIG. 1. FIG. 2 also shows a series of corresponding latent images that may be formed within the once photoexposed photosensitive material layer 12′ or the twice photoexposed photosensitive material layer 12″.

As is illustrated within FIG. 2, a first photomask 16 is intended to comprise a transparent substrate 20 and an opaque material layer 22 located upon the transparent substrate 10. Although not specifically illustrated within the schematic plan-view diagram of FIG. 2, the first photomask 16 may alternatively comprise an alternating phase shift photomask, an attenuated phase shift photomask or an attenuated block mask.

The transparent substrate 20 typically comprises a transparent material such as but not limited to: a quartz material or a glass material. Typically, the transparent substrate 20 comprises a transparent quartz material that has a thickness from about 1 to about 3 mils.

The opaque material layer 22 typically comprises an opaque metal, such as a chromium metal or an aluminum metal. Chromium metal as an opaque material is particularly common. Typically, the opaque material layer 22 has a thickness from about 500 to about 2000 angstroms.

FIG. 2 also shows a latent image 13 that is located within a once photoexposed photosensitive material layer 12′ that has been once photoexposed using the first set of photoexposure conditions that use the first mask 16 and the first photoexposure apparatus 14. The latent image 13 corresponds generally with the opaque material layer 22 located upon the transparent substrate 20 within the first mask 16, but the latent image 13 generally has additional curvature in comparison with the opaque material layer 22.

FIG. 2 also shows second photomasks 16a′ and 16b′ that may alternatively be used in a second photoexposure of the once photoexposed photosensitive material layer 12′ to form a twice photoexposed photosensitive material layer 12″. The embodiment intends that either the second mask 16a′ or the second mask 16b′ may be used subsequent to the first mask 16, but typically not both of the second mask 16a′ and the second mask 16b′.

Each of the second mask 16a′ and the second mask 16b′ also comprises a transparent substrate that is not otherwise specifically illustrated in FIG. 2. Each of the second mask 16a′ and the second mask 16b′ may also comprise an optional attenuator layer 26 that is exposed beneath an opaque material layer 24. Alternatively, each of the second mask 16a′ and the second mask 16b′ may comprise a binary mask. Within the second photomask 16b′, portions of the attenuator layer 26 may comprise sub-lithographic features that act to attenuate a total radiation intensity, and thus in some instances produce a “grey” effect.

Within the second mask 16a′ or the second mask 16b′ the opaque layer 24 may comprise opaque materials and have dimensions analogous to the opaque layer 22 within the first mask 16 that is also illustrated in FIG. 2.

With respect to the attenuator layer 26, attenuator materials are generally known in the photomask fabrication art. Attenuator materials typically transmit from about 2 to about 20 percent of photoexposure radiation (i.e., from about 80 to about 98 percent attenuation), and most typically transmit about 6 percent incoming photoexposure radiation. Several attenuator materials are in particular known in the semiconductor fabrication art. Non-limiting examples include several silicides, oxides and silicates of several elements, as well as amorphous carbon attenuator materials. Molybdenum silcide attenuator materials are generally common, and at a thickness from about 50 to about 1000 angstroms molybdenum silicide materials attenuate about 94 percent of incoming photoexposure radiation.

FIG. 2 finally illustrates a latent image 13′ within a twice photoexposed photosensitive material layer 12″ that results from a second photoexposure of the once photoexposed photosensitive material layer 12′ that is also illustrated in FIG. 2. As is illustrated in FIG. 2, the latent image 13′ comprises a notch 9 at a lower portion of the latent image 13′. The notch 9 allows for an adjustment of a location dependent critical dimensional variability of the latent image 13 in accordance with the objects disclosed above.

FIG. 3 illustrates an alternative ordering of the same photomasks that are illustrated in FIG. 2, as well as corresponding plurality of latent images that is formed within a once photoexposed photosensitive material layer 12′ and a twice photoexposed photosensitive material layer 12″ as a result of that alternative ordering.

FIG. 3 first shows the secondary (i.e., trim) mask constructions that may be used as a first mask 16a or a first mask 16b. In accordance with above disclosure, photoexposing a photosensitive material layer 12 upon a substrate 10 while using a first set of photoexposure conditions that use the first photoexposure apparatus 14 and either of the first mask 16a or the first mask 16b within the context of this particular embodiment does not yield any latent image within the once photoexposed photosensitive material layer 12′, since the embodiments in general contemplate that one of the first set of photoexposure conditions and the second set of photoexposure conditions is sub-lithographic.

FIG. 3 finally shows a second photomask 16′ that corresponds with first photomask 16 within the schematic diagram of FIG. 2. As is illustrated within FIG. 3, a second photoexposure of the once photoexposed photosensitive material layer 12′ to form the twice photoexposed photosensitive material layer 12″ while using the second photoexposure apparatus 14′ that is illustrated in FIG. 1 and while using a second set of photoexposure conditions that includes the second mask 16′ yields the same second latent image 13′ with the notch 9 that is illustrated within FIG. 2. In accordance with disclosure above, the notch 9 within the second latent image 13′ assists in addressing location dependent critical dimensional variability within a patterned layer that results from development of the twice photoexposed photosensitive material layer 12″ (i.e., when formed of a photoresist material) that is illustrated in FIG. 3.

The Table that follows lists a series of options for the first photoexposure apparatus 14 (Tool 1), the first mask 16 (Mask 1), the second photoexposure apparatus 14′ (Tool 2) and the second mask 16′ (Mask 2) in accordance with above disclosure within the context of FIG. 1. The options for the first photoexposure apparatus 14, the first mask 16, the second photoexposure apparatus 14′ and the second mask 16′ are not intended as limiting of the invention, but merely rather as exemplary embodiments that may be used within the context of the invention.

Within Table I, PSM is intended as phase shift mask; COG is intended as chrome-on-glass mask. The numerical values listed for the tools are intended as photoexposure wavelengths. NA is intended to represent numerical aperture.

### EXAMPLES

| Tool 1 | Mask 1 | Tool 2 | Mask 2 |
|---|---|---|---|
| 193 | PSM | 248 | COG |
| 193 | COG | 248 | COG |
| 193 | PSM | 365 | COG |
| 193i | PSM | 193 | PSM |
| 193i | PSM | 193 | COG |
| 193i 1.2 NA | COG | 193i 0.93 NA | COG |
| 193 | PSM | e-beam | N/A |

Illustrated in the foregoing Table is a plurality of photoexposure examples within the context of the invention, but not limiting the invention. Also intended as an embodiment are immersion photolithographic methods (i.e., that use a fluorinated fluid) that may be paired with non-immersion photolithographic methods.

The foregoing embodiments illustrate the invention which comprises methods for photoexposing a photosensitive material layer (i.e., typically a photoresist layer ) located upon a substrate. The methods use a first set of photoexposure conditions that use a first photoexposure apparatus and a second set of photoexposure conditions that use a second photoexposure apparatus different from the first photoexposure apparatus. The use of a first photoexposure apparatus different than the second photoexposure apparatus allows for efficiency when photoexposing a photoresist layer to form a latent pattern within the photoexposed photoresist layer.

The invention also contemplates that one of the set of first photoexposure conditions and the second of second photoexposure conditions does not form a latent image within a photoexposed photoresist layer.

The preferred embodiments of the invention are illustrative of the invention rather than limiting of the invention. Revisions and modifications may be made to methods, materials, structures and dimensions in accordance with the preferred embodiments while still providing an embodiment in accordance with the invention, further in accordance with the accompanying claims.

What is claimed is:

1. A photolithographic method comprising:
photoexposing a photosensitive material layer located over a substrate while using a first set of photoexposure conditions that includes use of a first photoexposure apparatus to form a once photoexposed photosensitive material layer located over the substrate; and
photoexposing the once photoexposed photosensitive material layer located over the substrate while using a second set of photoexposure conditions that include use of a second photoexposure apparatus different from the first photoexposure apparatus to form a twice photoexposed photosensitive material layer located over the substrate, where one of the first set of photoexposure conditions and the second set of photoexposure conditions does not form a latent image within the photosensitive material layer.

2. The method of claim 1 wherein the photoexposing the photosensitive material layer comprises photoexposing a photoresist layer to form a once photoexposed photoresist layer.

3. The method of claim 2 wherein the photoexposing the once photoexposed photosensitive material layer comprises photoexposing the once photoexposed photoresist layer to form a twice photoexposed photoresist layer.

4. The method of claim 3 further comprising developing the twice photoexposed photoresist layer to form a patterned photoresist layer.

5. The method of claim 1 wherein the other of the first set of photoexposure conditions and the second set of photoexposure conditions does form a latent image within the photosensitive layer.

6. The method of claim 1 wherein the first set of photoexposure conditions uses a first mask selected from the group consisting of an alternating phase shift mask, an attenuated phase shift mask and a binary mask.

7. The method of claim 1 wherein the set of second photoexposure conditions uses a second mask different from the first mask and also selected from the group consisting of an alternating phase shift mask, an attenuated phase shift mask and a binary mask.

8. The method of claim 1 wherein the first photoexposure apparatus is a projection photoexposure apparatus.

9. The method of claim 1 wherein the second photoexposure apparatus is a projection photoexposure apparatus.

10. The method of claim 1 wherein the first set of photoexposure conditions does not form the latent image.

11. The method of claim 1 wherein the second set of photoexposure conditions does not form the latent image.

12. The method of claim 1 wherein the first set of photoexposure conditions uses a first photoexposure radiation and the second set of photoexposure conditions uses a different second photoexposure radiation, each of the first photoexposure radiation and the second photoexposure radiation selected from the group consisting of 365 nm, 248 nm, 193 nm, electron beam and x-ray photoexposure radiations.

13. The method of claim 1 further comprising thermally annealing the once photoexposed photosensitive material layer located over the substrate at a temperature from about 60 to about 200 degrees centigrade prior to photoexposing the once photoexposed photosensitive material layer while using the second set of photoexposure conditions

14. A photolithographic method comprising:
photoexposing a photosensitive material layer located over a substrate while using a first set of primary photoexposure conditions that includes use of a first photoexposure apparatus to form a once photoexposed photosensitive material layer located over the substrate; and
photoexposing the once photoexposed photosensitive material layer located over the substrate while using a second set of secondary photoexposure conditions that include use of a second photoexposure apparatus different from the first photoexposure apparatus to form a twice photoexposed photosensitive material layer located over the substrate, where the second set of secondary photoexposure conditions alone do not form a latent image within the photosensitive material layer.

15. The method of claim 14 wherein the photoexposing the photosensitive material layer comprises photoexposing a photoresist layer to form a once photoexposed photoresist layer.

16. The method of claim 15 wherein the photoexposing the once photoexposed photosensitive material layer comprises photoexposing the once photoexposed photoresist layer to form a twice photoexposed photoresist layer.

17. The method of claim 16 further comprising developing the twice photoexposed photoresist layer to form a patterned photoresist layer.

18. The method of claim 14 wherein the first set of primary photoexposure conditions uses a first photoexposure radiation and the second set of secondary photoexposure conditions uses a different second photoexposure radiation, each of the first photoexposure radiation and the second photoexposure radiation selected from the group consisting of 365 nm, 248 nm, 193 nm, electron beam and x-ray photoexposure radiations.

19. The method of claim 14 further comprising thermally annealing the once photoexposed photosensitive material layer located over the substrate at a temperature from about 60 to about 200 degrees centigrade prior to photoexposing the once photoexposed photosensitive material layer while using the second set of secondary photoexposure conditions

20. A photolithographic method comprising:
photoexposing a photosensitive material layer located over a substrate while using a first set of secondary photoexposure conditions that includes use of a first photoexposure apparatus to form a once photoexposed photosensitive layer located over the substrate and absent a latent image; and
photoexposing the once photoexposed photosensitive material layer located over the substrate while using a second set of primary photoexposure conditions that includes use of a second photoexposure apparatus different from the first photoexposure apparatus to form a twice photoexposed photosensitive layer located over the substrate and including a latent image.

21. The method of claim 20 wherein the photoexposing the photosensitive material layer comprises photoexposing a photoresist layer to form a once photoexposed photoresist layer.

22. The method of claim 21 wherein the photoexposing the once photoexposed photosensitive material layer comprises photoexposing the once photoexposed photoresist layer to form a twice photoexposed photoresist layer.

23. The method of claim 22 further comprising developing the twice photoexposed photoresist layer to form a patterned photoresist layer.

24. The method of claim 19 wherein the first set of secondary photoexposure conditions uses a first photoexposure radiation and the second set of primary photoexposure conditions uses a different second photoexposure radiation, each of the first photoexposure radiation and the second photoexposure radiation selected from the group consisting of 365 nm, 248 nm, 193 nm, electron beam and x-ray photoexposure radiations.

25. The method of claim 19 further comprising thermally annealing the once photoexposed photosensitive material layer located over the substrate at a temperature from about 60 to about 200 degrees centigrade prior to photoexposing the once photoexposed photosensitive material layer while using the second set of primary photoexposure conditions
